(19) United States
(12) Patent Application Publication
(10) Pub. No.: US 2026/0293776 A1
(43) Pub. Date: Sep. 24, 2026

(54) SEMICONDUCTOR MODULE ARRANGEMENT

(71) Applicant: Infineon Technologies AG, Neubiberg (DE)

(72) Inventors: Thomas Raker, Geseke (DE); Andressa Colvero Schittler, Ense (DE); Olaf Rüdiger Hohlfeld, Warstein / Suttrop (DE); Alexander Herbrandt, Soest (DE)

(21) Appl. No.: 19/571,717

(22) Filed: Mar. 19, 2026

(30) Foreign Application Priority Data
Mar. 19, 2025 (DE) 102025110576.6

(51) Int. Cl. H10W 90/10; H10W 70/654; H10W 90/00; H10W 70/66; H10W 72/00

(52) U.S. Cl. CPC H10W 90/10; H10W 70/654; H10W 90/735; H10W 90/753; H10W 90/756; H10W 70/66; H10W 72/823; H10W 72/884

(57) ABSTRACT

A semiconductor module arrangement includes: a substrate having a metallization layer arranged on a dielectric insulation layer and including first, second and third sections; two or more controllable semiconductor elements each including first, second and third contact pads; and one or more freewheeling elements each including first and second contact pads. The second contact pad of the controllable semiconductor elements and the second contact pad of the freewheeling element(s) are electrically coupled to the first section. The first contact pad of the controllable semiconductor elements are electrically coupled to one another by a metal layer that continuously extends between the controllable semiconductor elements and is electrically coupled to the first contact pad of the freewheeling element(s) and to the second section by more electrical connection elements. The third contact pads of the controllable semiconductor elements are electrically coupled to the third section by one or more electrical connection elements.

### TECHNICAL FIELD

The instant disclosure relates to semiconductor module arrangements.

### BACKGROUND

Power semiconductor module arrangements often include at least one semiconductor substrate arranged in a housing. A semiconductor arrangement including a plurality of controllable semiconductor elements (e.g., IGBTs, MOSFETs, HEMTs, etc.) is arranged on each of the at least one substrate. Each substrate usually comprises a substrate layer (e.g., a ceramic layer), a first metallization layer deposited on a first side of the substrate layer, and, optionally, a second metallization layer deposited on a second side of the substrate layer. The controllable semiconductor elements are mounted, for example, on the first metallization layer. The second metallization layer may optionally be attached to a base plate or heat sink. In many applications, two or more individual controllable semiconductor elements are electrically coupled in parallel to each other in order to fulfill requirements concerning a current capability of the arrangement. However, unwanted oscillations may occur, for example, when controllable semiconductor elements that are electrically coupled in parallel are switched on and off, or when freewheeling elements are switched in parallel. One type of oscillation that may occur are so-called inter-chip oscillations, where the parasitic capacitances of the controllable semiconductor elements oscillate against parasitic inductances that are present between the respective controllable semiconductor elements. Such oscillations may cause EMI (electromagnetic interference) problems and/or unwanted voltage spikes that can cause damage to the chip gate oxide.

Hence, there is a general need for a semiconductor module arrangement in which oscillations, and in particular inter-chip oscillations, are significantly reduced.

### SUMMARY

A semiconductor module arrangement includes a first substrate including a dielectric insulation layer and a first metallization layer arranged on a surface of the dielectric insulation layer, wherein the first metallization layer includes a first section, a second section, and a third section, two or more controllable semiconductor elements, each controllable semiconductor element of the two or more controllable semiconductor elements including a first contact pad, a second contact pad, and a third contact pad, and one or more freewheeling elements, each freewheeling element of the one or more freewheeling elements including a first contact pad and a second contact pad, wherein the second contact pads of the two or more controllable semiconductor elements and the second contact pads of the one or more freewheeling elements are electrically coupled to the first section, the first contact pads of the controllable semiconductor elements of the two or more controllable semiconductor elements are electrically coupled to one another by means of a metal layer, wherein the metal layer continuously extends between the controllable semiconductor elements of the two or more controllable semiconductor elements, the metal layer is electrically coupled to each first contact pad of the one or more freewheeling elements and to the second section by means of one or more electrical connection elements, and the third contact pads of the controllable semiconductor elements of the two or more controllable semiconductor elements are electrically coupled to the third section by means of one or more electrical connection elements.

The invention may be better understood with reference to the following drawings and the description. The components in the figures are not necessarily to scale, emphasis instead being placed upon illustrating the principles of the invention. In the figures, like referenced numerals designate corresponding parts throughout the different views.

### BRIEF DESCRIPTION OF THE DRAWINGS

FIG. 1 is a cross-sectional view of a semiconductor module arrangement.

FIG. 2 schematically illustrates a top view of a conventional semiconductor module arrangement.

FIG. 3 is a circuit diagram of a half-bridge arrangement.

FIG. 4 schematically illustrates a top view of another conventional semiconductor module arrangement.

FIG. 5 schematically illustrates a top view of a semiconductor module arrangement according to embodiments of the disclosure.

FIG. 6 schematically illustrates a top view of a semiconductor module arrangement according to further embodiments of the disclosure.

FIG. 7 schematically illustrates a top view of a semiconductor module arrangement according to even further embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element, or include at least two individual electrically conductive elements connected in series and/or parallel. Electrical lines may include metal and/or semiconductor material, and may be permanently electrically conductive (i.e., non-switchable). An electrical line may have an electrical resistivity that is independent from the direction of a current flowing through it. A semiconductor body as described herein may be made of (doped) semiconductor material and may be a semiconductor chip or be included in a semiconductor chip. A semiconductor body has electrically connecting pads and includes at least one semiconductor element with electrodes. The pads are electrically connected to the electrodes which includes that the pads are the electrodes and vice versa.

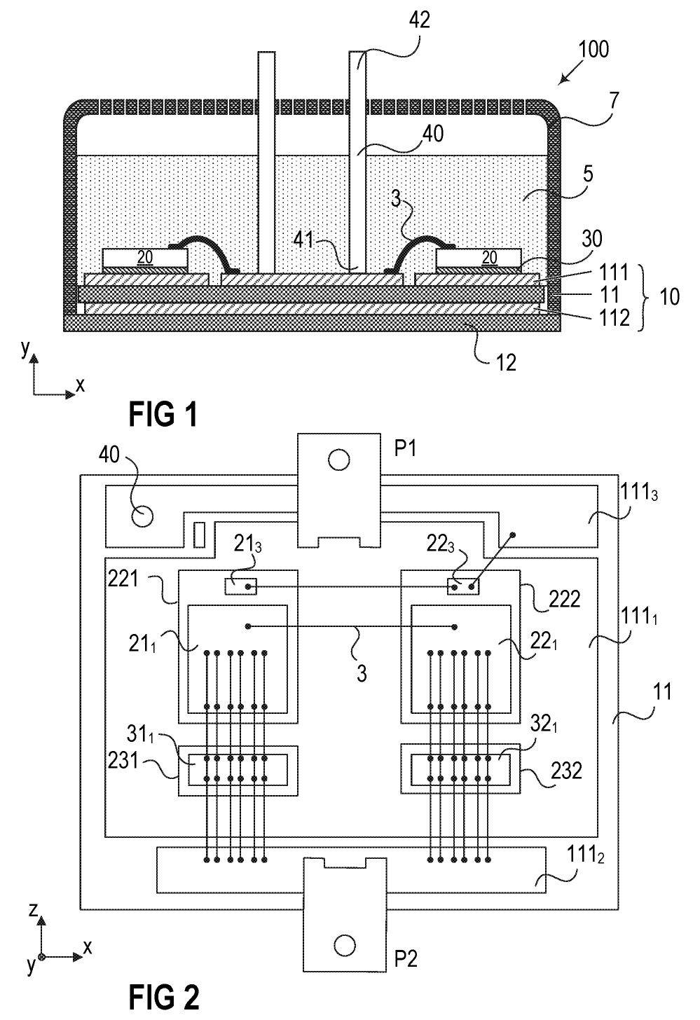

Referring to FIG. 1, a cross-sectional view of a semiconductor module arrangement 100 is schematically illustrated. The semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1µm and about 50µm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 is arranged on a base plate 12 which forms a base surface of the housing 7, while the housing 7 itself solely comprises sidewalls and a cover. This, however, is only an example. It is also possible that the housing 7 further comprises a base surface, and the substrate 10 and (optionally) the base plate 12 be arranged inside the housing 7 and on the base surface of the housing 7. In some power semiconductor module arrangements 100, more than one substrate 10 is arranged on a single base plate 12 or on a base surface of a housing 7. According to another example, the base plate 12 is omitted and the substrate 10 itself forms a base surface of the housing 7.

One or more semiconductor bodies 20 may be arranged on the at least one substrate 10. Each of the semiconductor bodies 20 arranged on the at least one substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), and/or any other suitable controllable or non-controllable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes three different sections. This, however, is only an example. Any other number of sections is possible. Different semiconductor bodies 20 may be mounted to the same or to different sections of the first metallization layer 111. Different sections of the first metallization layer 111 may have no electrical connection or may be electrically connected to one or more other sections using electrical connections 3 such as, e.g., bonding wires. Electrical connections 3 may also include connection plates or conductor rails, for example, to name just a few examples. The one or more semiconductor bodies 20 may be electrically and mechanically connected to the substrate 10 by an electrically conductive connection layer 30. Such an electrically conductive connection layer 30 may be a solder layer, a layer of an electrically conductive adhesive, or a layer of a sintered metal powder, e.g., a sintered silver powder, for example. According to other examples, it is also possible that the second metallization layer 112 is a structured layer. It is further possible to omit the second metallization layer 112 altogether.

The power semiconductor module arrangement 100 further includes terminal elements 4. Only two terminal elements 4 are schematically illustrated in FIG. 1. A power semiconductor module arrangement 100, however, generally may include only one, or more than two terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of each of the terminal elements 4 protrudes out of the housing 7. The terminal elements 4 may be electrically contacted from the outside at their respective second ends 42. A first part of the terminal elements 4 may extend through the inside of the housing 7 in a vertical direction y. The vertical direction y is a direction perpendicular to a top surface of the substrate 10, wherein the top surface of the substrate 10 is a surface on which at least one semiconductor body 20 is mounted. The terminal elements 4 illustrated in FIG. 1, however, are only an example. Terminal elements 4 may be implemented in any other way and may be arranged anywhere within the housing 7. For example, one or more terminal elements 4 may be arranged close to or adjacent to the sidewalls of the housing 7. Terminal elements 4 could also protrude through the sidewalls of the housing 7 instead of through the cover. The first end 41 of a terminal element 4 may be electrically and mechanically connected to the substrate 10 by means of an electrically conductive connection layer, for example (not explicitly illustrated for the terminal elements 4 in FIG. 1). Such an electrically conductive connection layer may be a solder layer, a layer of an electrically conductive adhesive, or a layer of a sintered metal powder, e.g., a sintered silver (Ag) powder, for example. The first end 41 of a terminal element 4 may also be electrically coupled to the substrate 10 via one or more electrical connections 3, for example. The second ends 42 of the terminal elements 4 may optionally be connected to a printed circuit board, for example (not illustrated in FIG. 1).

With further reference to FIG. 1, the semiconductor module arrangement 100 may further include an encapsulant 5. The encapsulant 5 may consist of or include a silicone gel or may be a rigid molding compound, for example. The encapsulant 5 may at least partly fill the interior of the housing 7, thereby covering the components and electrical connections that are arranged on the substrate 10. The terminal elements 4 may be partly embedded in the encapsulant 5. At least their second ends 42, however, are not covered by the encapsulant 5 and protrude from the encapsulant 5 through the housing 7 to the outside of the housing 7. The encapsulant 5 is configured to protect the components and electrical connections of the semiconductor module arrangement 100, in particular the components arranged on the substrate 10 and inside the housing 7, from certain environmental conditions and mechanical damage.

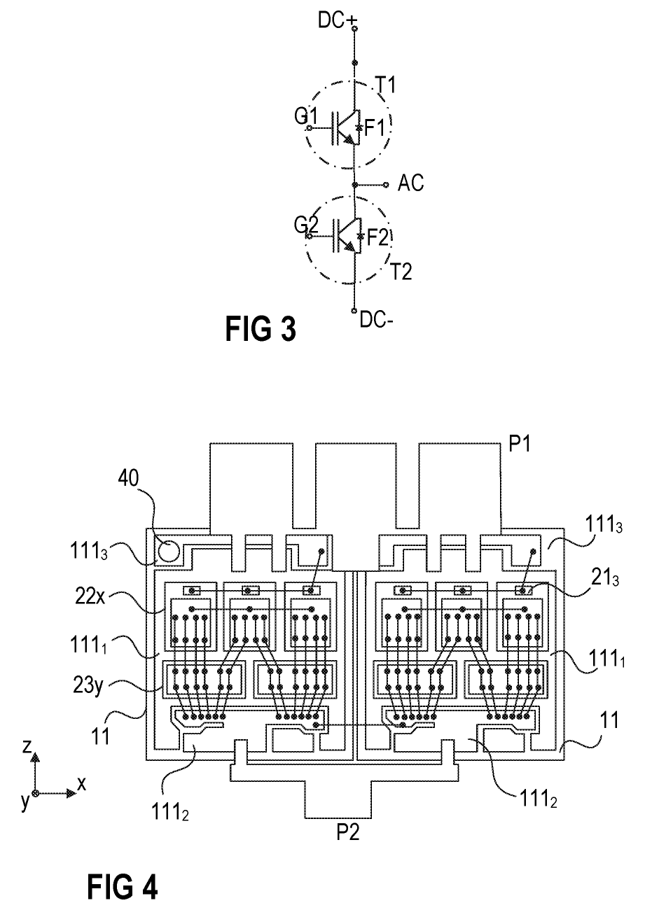

As has been described above, the semiconductor bodies 20 arranged on the substrate 10 may form a semiconductor arrangement. According to one example, the semiconductor bodies 20 may form a half-bridge arrangement. A circuit diagram of a half-bridge arrangement is schematically illustrated in FIG. 3. A half-bridge arrangement generally comprises two controllable semiconductor elements T1, T2 arranged in series between a first terminal and a second terminal. The first terminal may be electrically coupled to a first electrical potential (e.g., positive potential, DC+), and the second terminal may be electrically coupled to a second electrical potential (e.g., negative potential, DC-) that is different from the first electrical potential. A common node between the two controllable semiconductor elements T1, T2 is generally connected to or forms an output node, AC. A first freewheeling element F1 is generally coupled in parallel to the first controllable semiconductor element T1, and a second freewheeling element F2 is coupled in parallel to the second controllable semiconductor element T2. In a semiconductor module arrangement, each of the first controllable semiconductor element T1, the second controllable semiconductor element T2, the first freewheeling element F1, and the second freewheeling element F2 may be implemented by means of two or more semiconductor bodies 20. For example, the first controllable semiconductor element T1 as illustrated in FIG. 3 may be implemented by means of two or more semiconductor bodies 20, each semiconductor body 20 comprising a controllable semiconductor element. The two or more controllable semiconductor elements are coupled in parallel to form the first controllable semiconductor element T1. In the half-bridge arrangement illustrated in FIG. 3, the first controllable semiconductor element T1 is often referred to as high-side driver/switch, and the second controllable semiconductor element T2 is often referred to as low-side driver/switch. It is noted that the half-bridge arrangement as exemplarily illustrated in FIG. 3 is only an example. Semiconductor elements may generally be similarly arranged in any other kind of semiconductor arrangement.

Now referring to FIG. 2, a top view of a conventional semiconductor module arrangement is schematically illustrated. The semiconductor module arrangement comprises a substrate 10 comprising a dielectric insulation layer 11 and a first metallization layer 111 arranged on a surface of the dielectric insulation layer 11, wherein the first metallization layer 111 comprises a first section 111₁, a second section 111₂, and a third section 111₃. The semiconductor arrangement further comprises two controllable semiconductor elements 221, 222, each controllable semiconductor element 221, 222 of the two controllable semiconductor elements 221, 222 comprising a first contact pad 21₁, 22₁, a second contact pad, and a third contact pad 21₃, 22₃. The semiconductor module arrangement further comprises two freewheeling elements 231, 232, each freewheeling element 231, 232 of the two freewheeling elements 231, 232 comprising a first contact pad 31₁, 32₁, and a second contact pad. The second contact pads of the two controllable semiconductor elements 221, 222 and the second contact pads of the two or more freewheeling elements 231, 232 are electrically coupled to the first section 111₁.

In the arrangement illustrated in FIG. 2, the controllable semiconductor elements 221, 222 and the freewheeling elements 231, 232 are implemented as so-called vertical devices, and the second contact pads of the two controllable semiconductor elements 221, 222 and the second contact pads of the two or more freewheeling elements 231, 232 are electrically coupled to the first section 111₁by means of electrically conductive connection layers and are therefore not visible in the top view of FIG. 2. Implementing the controllable semiconductor elements 221, 222 and the freewheeling elements 231, 232 as vertical devices, however, is only an example. Instead, the devices may also be implemented as so-called lateral devices. In lateral devices, all contact pads are arranged on a surface of the respective device that faces away from the respective substrate 10. If the controllable semiconductor elements 221, 222 and the freewheeling elements 231, 232 are implemented as lateral devices, the second contact pads of the two controllable semiconductor elements 221, 222 and the second contact pads of the two or more freewheeling elements 231, 232 may be electrically coupled to the first section 111₁by means of one or more electrical connection elements 3.

The first contact pad 21₁, 22₁, of each controllable semiconductor element 221, 222 of the two controllable semiconductor elements 221, 222 is electrically coupled to the first contact pad 31₁, 32₁, of one of the two freewheeling elements 231, 232, and to the second section 111₂by means of one or more electrical connection elements 3. The third contact pads 21₃, 22₃, of the two controllable semiconductor elements 221, 222 are electrically coupled to each other by means of an electrical connection element 3. The third contact pad 22₃, of one of the two controllable semiconductor elements 221, 222 is further electrically coupled to the third section 111₃by means of an electrical connection element 3. Further, the first contact pads 21₁, 22₁, of the two controllable semiconductor elements 221, 222 may be electrically coupled to each other by means of an electrical connection element 3 (e.g., bonding wire or bonding ribbon).

The two controllable semiconductor elements 221, 222 as illustrated in FIG. 2 may form the first controllable semiconductor element T1, and the two freewheeling elements 231, 232 may form the first freewheeling element F1 of the half-bridge arrangement as illustrated in FIG. 3. Alternatively, the two controllable semiconductor elements 221, 222 may form the second controllable semiconductor element T2, and the two freewheeling elements 231, 232 may form the second freewheeling element F2, for example. Two or more individual controllable semiconductor elements 22x (semiconductor bodies) may be electrically coupled in parallel to each other to form one element of a semiconductor arrangement, for example, in order to fulfill requirements concerning a current capability of the semiconductor arrangement. However, when, for example, controllable semiconductor elements 22x that are electrically coupled in parallel are switched on and off, or two or more freewheeling elements are switched in parallel, oscillations may occur. One type of oscillation that may occur are so-called inter-chip oscillations, where the parasitic capacitances of the controllable semiconductor elements oscillate against parasitic inductances that are present between the respective controllable semiconductor elements. Such oscillations may cause EMI (electromagnetic interference) problems, especially if frequencies in the double to triple digit MHz-range occur in the semiconductor arrangement. Such high frequency currents flow between the semiconductor bodies that are electrically coupled in parallel to each other. This may result in electrical tracks of a length of up to several centimeters which may act as antennas. On the other hand, high peak voltages and high currents may occur inside the controllable semiconductor elements 22x, which may eventually lead to a degradation of the gate oxide of the controllable semiconductor elements 22x, or even to defects and the melting of structures in the chip internal gate network.

It is generally also possible that two or more of a plurality of controllable semiconductor elements 22x are arranged on a first substrate 10, and two or more of the plurality of semiconductor elements 22x are arranged on an additional second substrate 10. The same applies for the freewheeling elements 23x. This is schematically illustrated in FIG. 4. That is, in addition to the first substrate 10 described above with respect to FIG. 2, a semiconductor module arrangement may further comprise a second substrate 10. The second substrate 10 may be implemented in the same way as the first substrate 10 and as has been described with respect to FIG. 2, for example.

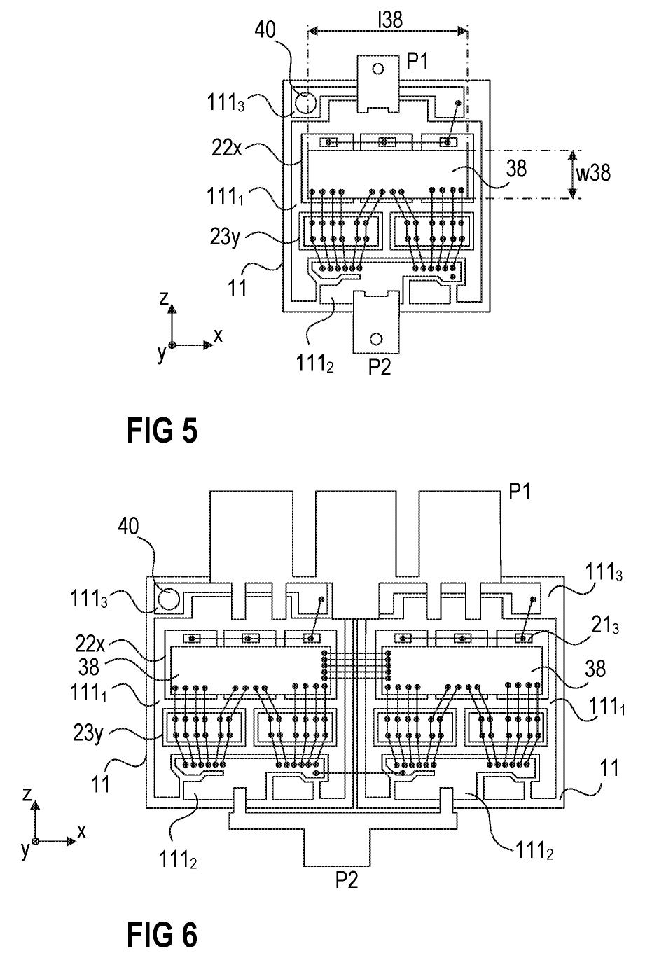

Now referring to FIG. 5, a top view of a semiconductor module arrangement according to embodiments of the disclosure is schematically illustrated. In the semiconductor module arrangements according to embodiments of the disclosure, oscillations, and in particular inter-chip oscillations, are significantly reduced or even avoided. A semiconductor module arrangement according to embodiments of the disclosure comprises a first substrate 10 comprising a dielectric insulation layer 11 and a first metallization layer 111 arranged on a surface of the dielectric insulation layer 11, wherein the first metallization layer 111 comprises a first section 111₁, a second section 111₂, and a third section 111₃. The semiconductor module arrangement further comprises two or more controllable semiconductor elements 22x, each controllable semiconductor element 22x of the two or more controllable semiconductor elements 22x comprising a first contact pad 2x₁, a second contact pad, and a third contact pad 2x₃, and one or more freewheeling elements 23x, each freewheeling element 23x of the one or more freewheeling elements 23x comprising a first contact pad 3x₁ and a second contact pad.

In the example illustrated in FIG. 5, the second contact pads of the controllable semiconductor elements 22x and the second contact pads of the freewheeling elements 23x are electrically coupled to the first section 111₁by means of electrically conductive connection layers (not visible in the top view illustrated in FIG. 5). As mentioned above, however, the second contact pads of the controllable semiconductor elements 22x and the second contact pads of the freewheeling elements 23x may instead be electrically coupled to the first section 111₁by means of electrical connection elements 3 (e.g., if controllable semiconductor elements 22x are implemented as lateral devices). The first contact pads 2x₁ of the controllable semiconductor elements 22x of the two or more controllable semiconductor elements 22x are electrically coupled to one another by means of a metal layer 38, wherein the metal layer 38 continuously extends between the controllable semiconductor elements 22x of the two or more controllable semiconductor elements 22x. The metal layer 38 is electrically coupled to each first contact pad 3x₁ of the one or more freewheeling elements 23x and to the second section 111₂by means of one or more electrical connection elements 3. In this way, the first contact pads 2x₁ of the controllable semiconductor elements 22x of the two or more controllable semiconductor elements 22x are also electrically coupled to the second section 111₂.The third contact pads 2x₃ of the controllable semiconductor elements 22x of the two or more controllable semiconductor elements 22x are electrically coupled to the third section 111₃by means of one or more electrical connection elements 3.

In the example illustrated in FIG. 4, two freewheeling elements 23y are exemplarily illustrated. However, in some applications only one freewheeling element may suffice. It is also possible that the semiconductor module arrangement comprises even more than two freewheeling elements. The third section 111₃, for example, may be electrically coupled to the outside of the semiconductor module arrangement by means of one or more terminal elements 40. One such terminal element 40 is exemplarily illustrated in FIG. 5.

In the arrangement illustrated in FIG. 5, and according to embodiments of the disclosure, the first contact pads 2x₁ of the controllable semiconductor elements 22x of the two or more controllable semiconductor elements 22x are electrically coupled to one another by means of the metal layer 38. The metal layer 38 provides a comparably large cross-sectional area as compared to the simple electrical connection element 3 (e.g., bonding wire or bonding ribbon) illustrated in the arrangement of FIG. 2. A single bonding wire or ribbon generally provides an electrical connection between the first contact pads 2x₁ of the controllable semiconductor elements 22x of the two or more controllable semiconductor elements 22x which has a high inductance. The metal layer 38, on the other hand, provides an electrical connection between the first contact pads 2x₁ of the controllable semiconductor elements 22x of the two or more controllable semiconductor elements 22x which has a comparably low inductance. That is, the effective inductances (e.g., source or emitter inductances) between the different controllable semiconductor elements 22x can be driven to a minimum value. In this way, oscillations, and in particular inter-chip oscillations, can be significantly reduced or even avoided. At the same time, each controllable semiconductor element 22x of the two or more controllable semiconductor elements 22x will show the (essentially) same turn-on behavior (dI/dt) as compared to an arrangement as illustrated in FIG. 2, for example.

The metal layer 38 may extend in parallel to a top surface of the first metallization layer 111, wherein a top surface of the first metallization layer 111 is a surface facing away from the dielectric insulation layer 11. According to some embodiments, the metal layer 38 may cover at least 50%, at least 75%, or at least 90% of the surface of each first contact pad 2ₓ₁. According to some examples, the metal layer 38 may be entirely flat such that the entire metal layer 38 extends in one and the same plane. It is, however, also possible that different sections of the metal layer 38 extend in different planes. That is, the metal layer 38, according to some examples, may be bent at least once along its length l38.

As mentioned above, the metal layer 38 may cover at least 50%, at least 75%, or at least 90% of the surface of each first contact pad 2x₁. That is, a width w38 of the metal layer in a second horizontal direction z perpendicular to the vertical direction y may essentially equal a width of the first contact pads 2x1 in the same direction. In the vertical direction y perpendicular to the top surface of the first metallization layer 111, the metal layer 38 may have a thickness of between 20µm and 800µm, for example. A length l38 of the metal layer 38 in a first horizontal direction x perpendicular to the vertical direction y and the second horizontal direction z generally depends on the number of controllable semiconductor elements 22x, a distance between two directly adjacent controllable semiconductor elements 22x, and a length of the first contact pads 2x₁ in the first horizontal direction x. As is schematically illustrated in FIG. 5, the metal layer 38 extends from a first outermost controllable semiconductor elements 22x over each intermediate controllable semiconductor element 22x to a second outermost controllable semiconductor element 22x.

An electrical connection between the metal layer 38, the first contact pads 3x₁ of the one or more freewheeling elements 23x, and the second section 111₂may be implemented similar to what has been described in FIG. 2. That is, the metal layer 38 may be electrically coupled to the first contact pads 3x₁ of the one or more freewheeling elements 23x, and to the second section 111₂by means of one or more electrical connection elements 3. Instead of the first contact pads 2x₁ of the controllable semiconductor elements 22x of the two or more controllable semiconductor elements 22x, however, the one or more electrical connection elements 3 are attached to the metal layer 38. That is, the metal layer 38 is arranged between the one or more electrical connection elements 3 and the first contact pads 2x₁ of the controllable semiconductor elements 22x of the two or more controllable semiconductor elements 22x. A connection element 3 (e.g., bonding wire) connected to the metal layer 38 may have a maximum thickness (e.g., diameter) of between 50µm and 500µm, for example. The one or more electrical connection elements 3 may comprise or consist of aluminum, an aluminum alloy, copper, a copper alloy, or gold, for example.

The two or more controllable semiconductor elements 22x are arranged between the metal layer 38 and the first metallization layer 111. According to some embodiments, the metal layer 38 may comprise or consist of aluminum, an aluminum alloy, copper, or a copper alloy. The metal layer 38 may be electrically and mechanically coupled to each first contact pad 2x₁ of the controllable semiconductor elements 22x of the two or more controllable semiconductor elements 22x by means of a solder layer, a layer of an electrically conductive adhesive, or a layer of a sintered metal powder, for example. The metal layer 38 may be implemented as a simple metal clip, for example.

Each of the two or more controllable semiconductor elements 22x may comprise a control electrode and a controllable load path between a first load electrode and a second load electrode. The load paths of the controllable semiconductor elements 22x are coupled in parallel to each other. The control electrode of a controllable semiconductor element 22x may be formed by or may be coupled to the third contact pad 2x₃ of the respective controllable semiconductor element 22x, the first load electrode may be formed by or may be coupled to the first contact pad 2x₁ of the respective controllable semiconductor element 22x, and the second load electrode may be formed by or may be coupled to the second contact pad of the respective controllable semiconductor element 22x. According to one example, the first contact pads 2x₁ of the one or more controllable semiconductor elements 22x are emitter pads, the second contact pads of the one or more controllable semiconductor elements 22x are collector pads, and the third contact pads 2x₃ of the one or more controllable semiconductor elements 22x are base (or gate) pads. According to an alternative example, the first contact pads 2x₁ of the one or more controllable semiconductor elements 22x are source or drain pads, the second contact pads of the one or more controllable semiconductor elements 22x are the respective other one of drain or source pads, and the third contact pads 2x₃ of the one or more controllable semiconductor elements 22x are gate pads.

Each of the one or more freewheeling elements 23x may include a first electrode and a second electrode. The first electrode of a freewheeling element 23x may be formed by or may be coupled to the first contact pad 3x₁ of the respective freewheeling element 23x, and the second electrode of a freewheeling element 23x may be formed by or may be coupled to the second contact pad of the respective freewheeling element 23x. The first contact pads 3x₁ of the two or more freewheeling elements 23x may be anode pads, and the second contact pads of the two or more freewheeling elements 23x may be cathode pads, for example, or vice versa.

The first section 111₁of the first metallization layer 111 may be electrically coupled to a first electrical potential P1 by means of a first bus bar, and the second section 111₂may be electrically coupled to a second potential P2 that is different from the first potential P1 by means of a second bus bar, for example.

Now referring to FIG. 6, a semiconductor module arrangement according to further embodiments of the disclosure is schematically illustrated. The semiconductor module arrangement, in addition to the first substrate 10, further comprise a second substrate 10 comprising a dielectric insulation layer 11 and a first metallization layer 111 arranged on a surface of the dielectric insulation layer 11, wherein the first metallization layer 111 comprises a first section 111₁, a second section 111₂, and a third section 111₃. The semiconductor module arrangement further comprises two or more controllable semiconductor elements 22x arranged on the second substrate 10, each controllable semiconductor element 22x of the two or more controllable semiconductor elements 22x comprising a first contact pad 2x₁, a second contact pad, and a third contact pad 2x₃, and one or more freewheeling elements 23x arranged on the second substrate 10, each freewheeling element 23x of the one or more freewheeling elements 23x comprising a first contact pad 3x₁ and a second contact pad. The second contact pads of the two or more controllable semiconductor elements 22x and the second contact pads of the one or more freewheeling elements 23x are electrically coupled to the first section 111₁of the first metallization layer 111 of the second substrate 10, the first contact pads 2x₁ of the controllable semiconductor elements 22x of the two or more controllable semiconductor elements 22x are electrically coupled to one another by means of a second metal layer 38, wherein the second metal layer 38 continuously extends between the controllable semiconductor elements 22x of the two or more controllable semiconductor elements 22x.

The second metal layer 38 is electrically coupled to each first contact pad 3x₁ of the one or more freewheeling elements 23x and to the second section 111₂by means of one or more electrical connection elements 3. The third contact pads 2x₃ of the controllable semiconductor elements 22x of the two or more controllable semiconductor elements 22x are electrically coupled to the third section 111₃by means of one or more electrical connection elements 3. The second metal layer 38 may be implemented similar to what has been described with respect to the metal layer 38 illustrated in FIG. 5.

The metal layer 38 of the first substrate 10 is electrically coupled to the metal layer 38 of the second substrate 10 by means of one or more electrical connection elements 3. That is, instead of connecting the first contact pads 2x₁ of the controllable semiconductor elements 22x of the two or more controllable semiconductor elements 22x arranged on the first substrate 10 to the first contact pads 2x₁ of the controllable semiconductor elements 22x of the two or more controllable semiconductor elements 22x arranged on the second substrate 10 by means of a single metal layer 38, the first contact pads 2x₁ of the controllable semiconductor elements 22x of the two or more controllable semiconductor elements 22x arranged on each substrate 10 are electrically connected to each other by means of separate metal layers 38. That is, for each substrate 10, a separate metal layer 38 is provided. When electrically coupling the metal layer 38 of the first substrate 10 to the metal layer 38 of the second substrate 10 by means of one or more electrical connection elements 3, this allows to test each substrate separately. In particular, each substrate 10 may be tested separately after the metal layers 38 have been arranged on the first contact pads 2x₁ of the controllable semiconductor elements 22x of the two or more controllable semiconductor elements 22x arranged on the substrates 10, and before electrically coupling the metal layers 38 of the different substrates 10 to each other by means of one or more electrical connection elements 3.

Electrically coupling the metal layers 38 of the different substrates 10 to each other by means of a single (exactly one, not more than one) electrical connection element 3 may suffice. However, according to some examples, the metal layers 38 of the different substrates 10 may be electrically coupled to each other by means of at least two, at least five, or at least ten electrical connection elements 3. As before, connection elements 3 may take the form of bonding wires, bonding ribbons, bonding plates, conducting rails or any other suitable connector. A substrate-to-substrate connection may generally be improved if more than one electrical connection 3 is used to form the respective substrate-to-substrate connection.

The third section 111₃of the first metallization layer 111 of the first substrate 10 may be electrically coupled to the third section 111₃of the first metallization layer 111 of the second substrate 10 by means of one or more electrical connection elements 3. Such connections are not visible behind the bus bar as illustrated in FIG. 6. The second section 111₂of the first metallization layer 111 of the first substrate 10 may be electrically coupled to the second section 111₂of the first metallization layer 111 of the second substrate 10 by means of one or more electrical connection elements 3.

In this way, the controllable semiconductor elements 22x arranged on the first substrate 10 may be coupled in parallel to the controllable semiconductor elements 22x arranged on the second substrate 10. The controllable semiconductor elements 22x arranged on the first substrate 10 and the controllable semiconductor elements 22x arranged on the second substrate 10 may together form the first controllable semiconductor element T1 as illustrated in FIG. 3, for example. Similarly, the freewheeling element(s) 23x arranged on the first substrate 10 and the freewheeling element(s) 23x arranged on the second substrate 10 may together form the first freewheeling element F1 of the half-bridge arrangement as illustrated in FIG. 3. It is alternatively also possible, for example, that the controllable semiconductor elements 22x arranged on the first substrate 10 and the controllable semiconductor elements 22x arranged on the second substrate 10 together form the second controllable semiconductor element T2, and the freewheeling element(s) 23x arranged on the first substrate 10 and the freewheeling element(s) 23x arranged on the second substrate 10 together form the second freewheeling element F2 of the half-bridge arrangement as illustrated in FIG. 3.

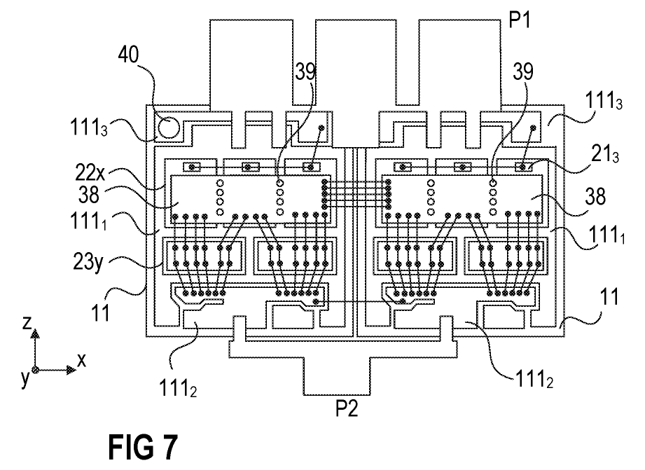

In the arrangements illustrated in FIGS. 5 and 6, the metal layers 38 are continuous layers. Now referring to FIG. 7, it is, however, also possible that a metal layer 38 comprises one or more holes 39 extending through the metal layer 38 in the vertical direction y. Each hole 39 of the one or more holes 39 may be arranged in a section of the metal layer 38 extending between two controllable semiconductor elements 22x of the two or more controllable semiconductor elements 22x.

As has been described with respect to FIG. 1 above, a semiconductor module arrangement may further comprise an encapsulant 5. An encapsulant 5 is generally formed by filling a liquid or viscous material into the housing 7, thereby covering the one or more substrates 10 arranged therein. The material is then cured (e.g., by applying heat) to form the encapsulant 5. When filling a liquid or viscous material on a substrate of a semiconductor module arrangement comprising a metal layer 38 without any holes, there is a risk that the liquid or viscous material does not reach areas below the metal layer 38 and between the different controllable semiconductor elements 22x. That is, cavities may remain between the metal layer 38 and the substrate 10. This may negatively affect the operation of the semiconductor module arrangement. When providing one or more holes 39 in the metal layer 38 in sections of the metal layer 38 extending between two controllable semiconductor elements 22x of the two or more controllable semiconductor elements 22x, the material forming the encapsulant 5 may flow through the holes 39 and towards the substrate 10. In this way, the risk of cavities forming below the metal layer 38 which are not filled with encapsulant 5 can be reduced. Further, the one or more holes 39 may increase the overall stability of the semiconductor substrate arrangement, as the one or more holes 39 may reduce any stress which may otherwise occur in the metal layer 38.

The semiconductor module arrangements according to the various embodiments described herein comprise a first substrate 10, and (optionally) a second substrate 10. It is, however, generally possible that a semiconductor substrate arrangement comprises even more than two substrates 10. Any further substrates 10 may be implemented in the same way as the first and the optional second substrate 10, and may be electrically coupled to the other substrates 10 similar to what has been described with respect to FIG. 6.

FIG. 5 schematically illustrates one substrate 10 with three controllable semiconductor elements 22x and two freewheeling elements 23x attached thereto. As mentioned above, it is generally possible that two or more than two controllable semiconductor elements 22x and/or less (i.e. only one) or more than two freewheeling elements 23x are arranged on a substrate 10 in order to form the first controllable semiconductor element T1 and the first freewheeling element F1, or the second controllable semiconductor element T2 and the second freewheeling element F2 of a semiconductor arrangement (see, e.g., half-bridge arrangement of FIG. 3). In the examples illustrated in FIGS. 5, 6, and 7, the number of controllable semiconductor elements 22x on each substrate 10 is greater than the number of freewheeling elements 23x on the same substrate 10. Each controllable semiconductor element 22x may be directly electrically coupled to only one of the freewheeling elements 23x on the same substrate 10 by means of one or more electrical connection elements 3, or to more than one of the freewheeling elements 23x on the same substrate 10.

By electrically coupling the first contact pads 2x₁ of the controllable semiconductor elements 22x of the two or more controllable semiconductor elements 22x to each other by means of a metal layer 38, a low-inductive connection (e.g., emitter or source connection) is provided between the different controllable semiconductor elements 22x on each substrate 10. In this way, effective source/emitter inductances may be driven to a minimum, and inter-chip oscillations may be significantly reduced or even avoided. Very good results may be achieved, for example, for high-frequency pole paths for drain-source voltages V_{DS} = 200V, and for low-frequency pole paths for all drain-source voltages.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor module arrangement, comprising:
a first substrate comprising a dielectric insulation layer and a first metallization layer arranged on a surface of the dielectric insulation layer, wherein the first metallization layer comprises a first section, a second section, and a third section;
two or more controllable semiconductor elements each comprising a first contact pad, a second contact pad, and a third contact pad; and
one or more freewheeling elements each comprising a first contact pad and a second contact pad,
wherein the second contact pad of the two or more controllable semiconductor elements and the second contact pad of the one or more freewheeling elements are electrically coupled to the first section,
wherein the first contact pad of the two or more controllable semiconductor elements are electrically coupled to one another by means of a metal layer,
wherein the metal layer continuously extends between the two or more controllable semiconductor elements,
wherein the metal layer is electrically coupled to each first contact pad of the one or more freewheeling elements and to the second section by one or more electrical connection elements, and
wherein the third contact pad of the two or more controllable semiconductor elements are electrically coupled to the third section by one or more electrical connection elements.

2. The semiconductor module arrangement of claim 1, wherein the metal layer extends in parallel to a top surface of the first metallization layer, and wherein a top surface of the first metallization layer is a surface facing away from the dielectric insulation layer.

3. The semiconductor module arrangement of claim 1, wherein the two or more controllable semiconductor elements are arranged between the metal layer and the first metallization layer.

4. The semiconductor module arrangement of claim 1, wherein the metal layer, in a vertical direction perpendicular to the top surface of the first metallization layer, has a thickness of between 20µm and 800µm.

5. The semiconductor module arrangement of claim 1, wherein the metal layer comprises aluminum, an aluminum alloy, copper, or a copper alloy.

6. The semiconductor module arrangement of claim 1, wherein the metal layer is electrically and mechanically coupled to each first contact pad of the two or more controllable semiconductor elements by a solder layer, a layer of an electrically conductive adhesive, or a layer of a sintered metal powder.

7. The semiconductor module arrangement of claim 1, wherein the metal layer covers at least 50%, at least 75%, or at least 90% of the surface of each first contact pad.

8. The semiconductor module arrangement of claim 1, wherein the metal layer comprises one or more holes extending through the metal layer in a vertical direction, and wherein each hole of the one or more holes is arranged in a section of the metal layer extending between two controllable semiconductor elements of the two or more controllable semiconductor elements.

9. The semiconductor module arrangement of claim 1, wherein the first section of the first metallization layer is electrically coupled to a first electrical potential by a first bus bar, and wherein the second section of the first metallization layer is electrically coupled to a second potential that is different from the first potential by a second bus bar.

10. The semiconductor module arrangement of claim 1, wherein:
the first contact pad of the two or more controllable semiconductor elements are emitter pads, the second contact pad of the two or more controllable semiconductor elements are collector pads, and the third contact pad of the two or more controllable semiconductor elements are base pads, or
the first contact pad of the two or more controllable semiconductor elements are source or drain pads, the second contact pad of the two or more controllable semiconductor elements are the respective other one of the drain or source pads, and the third contact pad of the two or more controllable semiconductor elements are gate pads.

11. The semiconductor module arrangement of claim 1, further comprising
a second substrate comprising a dielectric insulation layer and a first metallization layer arranged on a surface of the dielectric insulation layer, wherein the first metallization layer comprises a first section, a second section, and a third section;
two or more controllable semiconductor elements arranged on the second substrate and each comprising a first contact pad, a second contact pad, and a third contact pad; and
one or more freewheeling elements arranged on the second substrate and each comprising a first contact pad and a second contact pad,
wherein the second contact pad of the two or more controllable semiconductor elements and the second contact pad of the one or more freewheeling elements arranged on the second substrate are electrically coupled to the first section of the first metallization layer of the second substrate,
wherein the first contact pad of the two or more controllable semiconductor elements arranged on the second substrate are electrically coupled to one another by a metal layer of the second substrate that continuously extends between the two or more controllable semiconductor elements arranged on the second substrate,
wherein the metal layer of the second substrate is electrically coupled to each first contact pad of the one or more freewheeling elements arranged on the second substrate and to the second section of the first metallization layer of the second substrate by one or more electrical connection elements, and
wherein the third contact pad of the two or more controllable semiconductor elements arranged on the second substrate are electrically coupled to the third section of the first metallization layer of the second substrate by one or more electrical connection elements.

12. The semiconductor module arrangement of claim 11, wherein the metal layer of the first substrate is electrically coupled to the metal layer of the second substrate by one or more electrical connection elements.

13. The semiconductor module arrangement of claim 11, wherein:
the third section of the first metallization layer of the first substrate is electrically coupled to the third section of the first metallization layer of the second substrate by one or more electrical connection elements; and
the second section of the first metallization layer of the first substrate is electrically coupled to the second section of the first metallization layer of the second substrate by one or more electrical connection elements.
